(19) United States
(12) Patent Application Publication
(10) Pub. No.: US 2013/0307565 A1
(43) Pub. Date: Nov. 21, 2013

(54) TOUCH SENSOR AND METHOD OF MANUFACTURING THE SAME

(71) Applicants: Seung Hyun Ra, Gyunggi-do (KR); Chung Mo Yang, Gyunggi-do (KR)

(72) Inventors: Seung Hyun Ra, Gyunggi-do (KR); Chung Mo Yang, Gyunggi-do (KR)

(73) Assignee: SAMSUNG ELECTRO-MECHANICS CO., LTD., Gyunggi-do (KR)

(21) Appl. No.: 13/554,071

(22) Filed: Jul. 20, 2012

(30) Foreign Application Priority Data
May 15, 2012 (KR) 10-1012-0051662

(51) Int. Cl. G01R 27/00; G01R 3/00

(52) U.S. Cl. 324/649; 427/108

(57) ABSTRACT

Disclosed herein are a touch sensor and a method of manufacturing the same, the touch sensor including: a transparent substrate; a shielding film formed on one surface of the transparent substrate; a resin layer formed above the transparent substrate and one surface of the shielding film; and an electrode buried in one surface of the resin layer.

### CROSS REFERENCE TO RELATED APPLICATION

This application claims the benefit of Korean Patent Application No. 10-2012-0051662, filed on May 15, 2012, entitled “Touch Sensor and the Manufacturing Method”, which is hereby incorporated by reference in its entirety into this application.

### BACKGROUND OF THE INVENTION

1. Technical Field

The present invention relates to a touch sensor and a method of manufacturing the same.

2. Description of the Related Art

Recently, in touch screen panels mainly with smart phones or tablet PCs, a resistive film type has been rapidly changed with a capacitive type. A GFF type has been publicly applied to the capacitive type touch sensor, and assumes a configuration where two PET films are formed by depositing/patterning ITO on a lower surface of a window glass.

Meanwhile, as for touch sensors, GFF type or GG type glass sensors mainly with ITO films have been chiefly employed.

Also, the touch sensor is formed by electrode patterns and electrode wires around the edges of the electrode patterns. In the related art, the electrode wires are formed of an opaque metal material, and thus, a shielding film is disposed on the entire surface of the electrode wires. Therefore, the electrode wires are shielded by the shielding film.

However, since the electrode including the electrode wires and the electrode patterns is formed on one surface of the shielding film or one surface of a transparent substrate having the shielding film thereon dining forming thereof, a step height may be formed on the electrode due to the shielding film.

Therefore, it may be impossible to form the electrode in a mesh pattern due to this step height of the electrode.

### SUMMARY OF THE INVENTION

The present invention has been made in an effort to provide a touch sensor and a method of manufacturing the same, capable of reducing a step height between a shielding film and an electrode.

According to a preferred embodiment of the present invention, there is provided a touch sensor, including: a transparent substrate; a shielding film formed on one surface of the transparent substrate; a resin layer formed above the transparent substrate and one surface of the shielding film; and an electrode buried in one surface of the resin layer.

The transparent substrate may be formed of glass or a film.

The shielding film may be formed along an edge of one surface of the transparent substrate.

The resin layer may be formed of an imprint resin.

The electrode may include: electrode patterns sensing a touch; and electrode wires electrically connected to edges of the electrode patterns, the electrode wires being shielded by the shielding film when viewed in a direction of the other surface of the transparent substrate.

The electrode patterns may be formed of a metal mesh.

The electrode patterns and the electrode wires may be formed on the same plane.

The touch sensor may further include a protecting layer formed on one surface of the resin layer having the electrode buried therein.

According to another preferred embodiment of the present invention, there is provided a method of manufacturing a touch sensor, the method including: forming a shielding film on one surface of a transparent substrate; forming a resin layer above the transparent substrate and one surface of the shielding film; and burying and forming an electrode in one surface of the resin layer.

Here, in the forming of the shielding film, the shielding film may be formed along an edge of one surface of the transparent substrate.

The transparent substrate may be formed of glass or a film.

The method may further include, after the forming of the electrode, forming a protecting layer on one surface of the resin layer having the electrode buried therein.

The electrode may be formed in a metal mesh pattern.

The forming of the electrode may include forming electrode grooves in one surface of the resin layer, the electrode grooves formed with the electrode.

The resin layer may be formed of an imprint resin.

Here, in the forming of the electrode grooves, the electrode grooves may be formed by imprinting the resin layer.

The electrode may include: electrode patterns sensing a touch; and electrode wires electrically connected to the electrode patterns, wherein the electrode wires are shielded by the shielding film when viewed in a direction of the other surface of the transparent substrate.

Here, in the forming of the electrode grooves, the electrode grooves may be formed such that the electrode patterns and the electrode wires are formed on the same plane.

Here, in the forming of the electrode, the electrode may be formed in the electrode groove by plating or deposition.

The forming of the electrode may further include: forming a resist on one surface of the resist layer except for the electrode grooves; forming a metal layer on one surface of the resin layer; and removing the resist to form the electrode buried in the electrode groove.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a separate perspective view showing a touch sensor according to a preferred embodiment of the present invention;

FIG. 2 is a side cross-sectional view showing a touch sensor according to a preferred embodiment of the present invention;

FIG. 3 is a flow chart showing a method of manufacturing a touch sensor according to a preferred embodiment of the present invention; and

FIGS. 4 through 12 are cross-sectional views showing a method of manufacturing a touch sensor according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

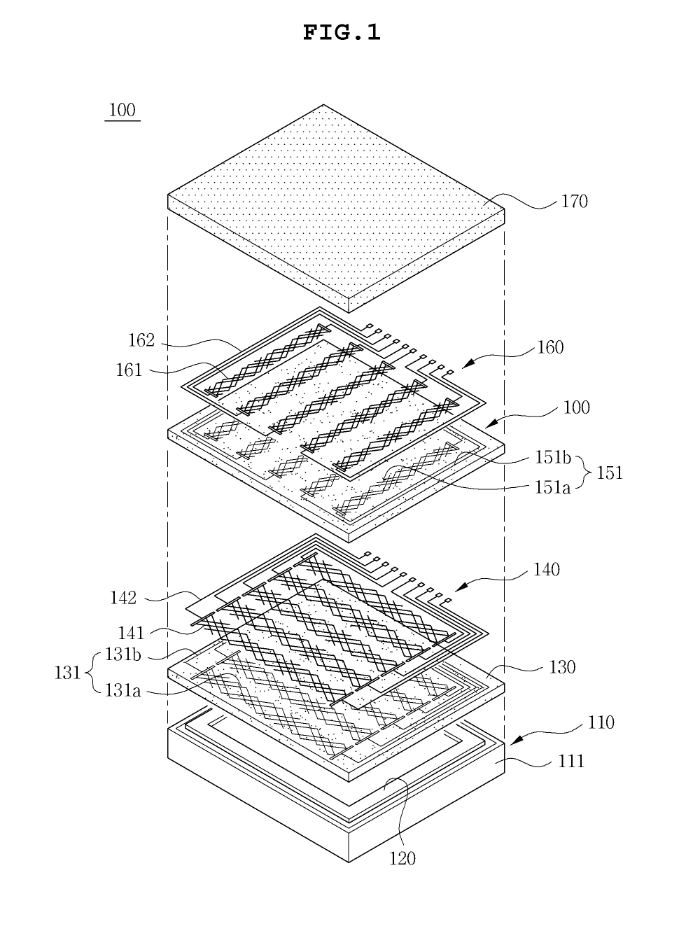

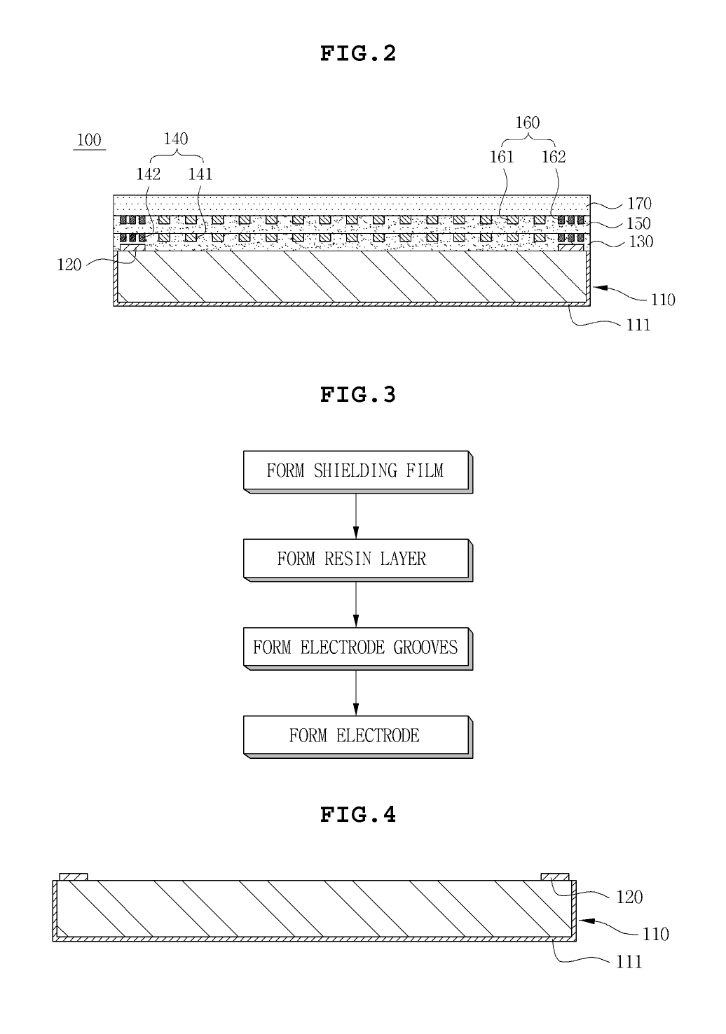

FIG. 1 is a separate perspective view showing a touch sensor according to a preferred embodiment of the present invention; and FIG. 2 is a side cross-sectional view showing a touch sensor according to a preferred embodiment of the present invention.

Referring to FIGS. 1 and 2, a touch sensor 100 according to a preferred embodiment of the present invention may include a transparent substrate 110, a shielding film 120, resin layers 130 and 150, and electrodes 140 and 160.

Hereinafter, referring to FIGS. 1 and 2, the touch sensor 100 according to the preferred embodiment of the present invention will be described in more detail.

Referring to FIGS. 1 and 2, the transparent substrate 110 is formed of glass or a film, and thus, a substrate part on which electrodes are formed. Here, the transparent substrate 110 may be formed in a square plate type having a predetermined thickness, but the shape of the transparent substrate 110 according to a preferred embodiment of the present invention is not limited thereto.

Referring to FIGS. 1 and 2, the resin layers 130 and 150 are formed above one surface of the transparent substrate 110. Here, the resin layers 130 and 150 may be formed of an imprint resin. Here, the imprint resin may be formed of a thermosetting resin or a thermoplastic resin, but a material for the resin layers according to a preferred embodiment of the present invention is not limited thereto. For example, the resin layer may also be formed of an acrylate-based resin. In addition, the resin layers 130 and 150 may include a first resin layer 130 and a second resin layer 150.

Referring to FIGS. 1 and 2, the electrodes 140 and 160 are formed above one surface of the transparent substrate 110 in a buried type. Here, one surface of the transparent substrate 110 indicates an upper surface of the transparent substrate 110 of FIG. 1, but one surface of the transparent substrate 110 of the present invention is not limited to the upper surface of the transparent substrate 110, and one surface of the transparent substrate may be, of course, a lower surface of the transparent substrate 110.

In addition, the electrodes 140 and 160 are comprised as touch electrodes, and may include electrode patterns 141 and 161 and electrode wires. Here, the electrodes 140 and 160 may include a first electrode 140 and a second electrode 160.

Here, the electrode patterns 141 and 161 are comprised of first electrode patterns 141 and second electrode patterns 161, and thus they may detect a touch. Here, since the constitution of the electrode patterns 141 and 161 sensing touch has been widely disclosed, detailed descriptions thereof will be omitted.

In addition, the electrode wires 142 and 162 are comprised of first electrode wires 142 and second electrode wires 162. Here, the first electrode wirings 142 receiving an electric signal from the first electrode patterns 141 are formed at edges of the first electrode patterns 141, and the second electrode wirings 162 receiving an electric signal from the second electrode patterns 161 are formed at edges of the second electrode patterns 161.

Also, the electrode patterns 141 and 161 may be made of metal mesh. Here, the metal mesh may be formed in a mesh pattern by using copper (Cu), aluminum (Al), gold (Au), silver (Ag), titanium (Ti), palladium (Pd), chrome (Cr), or a combination thereof.

Meanwhile, in the case where the first and second electrode patterns 141 and 161 are formed of copper (Cu), blackened treatment may be performed on the other surface of the first and second electrode patterns 141 and 161, to thereby prevent light from being deflected.

In addition, the electrode patterns 141 and 161 may be formed to have a line width of 7 μm or less and a pitch of 900 μm or less, to thereby improve visibility. However, the line width and the pitch of the first and second electrode patterns 141 and 161 according to a preferred embodiment of the present invention are not limited thereto.

Meanwhile, the electrode patterns 141 and 161 may be formed of metal silver formed by exposing/developing a silver salt emulsion layer, besides the above-described metal.

Referring to FIGS. 1 and 2, the shielding film 120 may be formed along an edge of one surface of the transparent substrate 110. Here, the shielding film 120 may be formed in a square band having a square hole formed in the central portion thereof.

Here, in the case where the electrode wires 142 and 162 are formed of metal such as a silver paste, the electrode wires 142 and 162 may be recognized from the outside. In order to prevent this, the shielding film 120 is provided. The shielding film 120 may be formed by printing an ink having low brightness, such as, black ink, on one surface of the transparent substrate 110. Therefore, in FIG. 2, the electrode wires 142 and 162 may be shielded by the shielding film 120 when viewed from an upper direction to a lower direction of the transparent substrate 110.

Meanwhile, referring to FIGS. 1 and 2, in the touch sensor 100 according to a preferred embodiment of the present invention, a chemical reinforcing layer 111 is formed on the other surface of the transparent substrate 110 except for one surface of the transparent substrate 110 above the electrodes 140 and 160 are formed.

Here, the chemical reinforcing layer 111 is a protecting layer for the transparent substrate 110 formed by coating a salt paste as a chemical reinforcing agent on a chemical reinforcing area of the transparent substrate 110. Here, the salt paste may contain salt, such as, potassium nitrate (KNO₃), potassium chloride (KCl), or the like, and ethanol based oil easily dissolving the salt and having excellent adsorbability to a glass surface, as a mixture medium. In addition, the chemical reinforcing agent may be printed by a silkscreen or roller coating method.

Meanwhile, referring to FIGS. 1 and 2, the touch sensor 100 according to a preferred embodiment of the present invention may further include a protecting layer 190 formed on one surface of the resin layer 150 in which the electrode 160 is buried. Here, the protecting layer 190 covers one surface of the resin layer 150, to thereby protect the electrode 160 formed in the resin layer 150 from moisture, impact, or other external surroundings. In addition, the protecting layer 190 may contain acrylate.

Resultantly, in the touch sensor 100 according to a preferred embodiment of the present to invention constituted as above, a step height between the shielding film 120 and the electrodes 140 and 160 can be reduced by forming the resin layers 130 and 150 above one surface of the transparent substrate 110 on which the shielding film 120 is formed, and burying the electrodes 140 and 160 in the resin layers 130 and 150, respectively. Further, due to this, the electrode patterns 141 and 161 and the electrode wires 142 and 162 may be simultaneously formed at the time of forming the electrodes 140 and 160 including the electrode patterns 141 and 161 and the electrode wires 142 and 162, and thus, the manufacturing time and the manufacturing cost of the touch sensor 100 can be reduced.

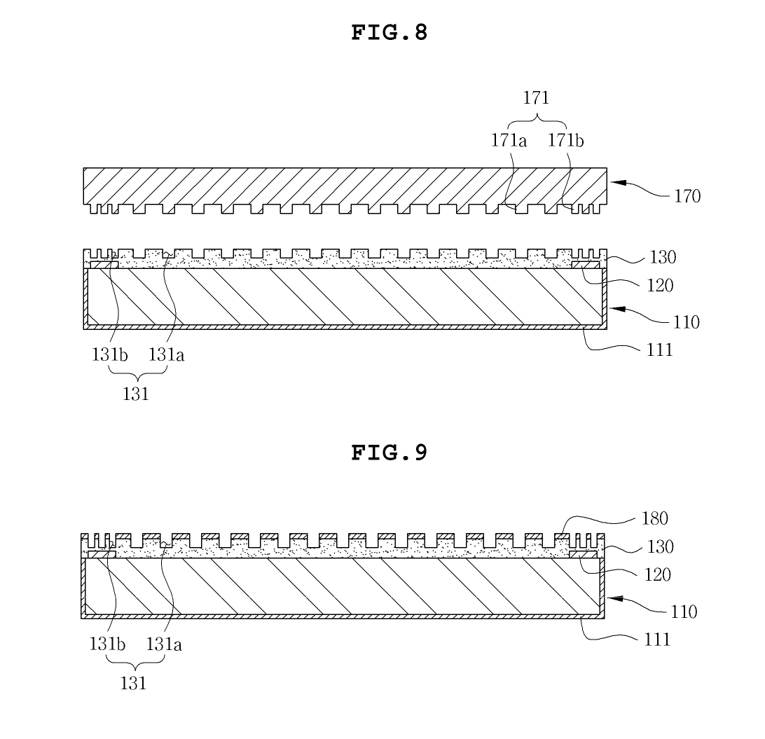

FIG. 3 is a flow chart showing a method of manufacturing a touch sensor according to a preferred embodiment of the present invention; and FIGS. 4 through 12 are cross-sectional views showing a method of manufacturing a touch sensor according to a preferred embodiment of the present invention.

Referring to FIG. 3, a method of manufacturing the touch sensor according to a preferred embodiment of the present invention may include forming a shielding film (S10); forming a resin layer (S20); forming electrode grooves (S30); and forming an electrode (S40).

Hereinafter, referring to FIGS. 3 and 12, the method of manufacturing a touch sensor according to a preferred embodiment of the present invention will be described in more detail. In addition, the method of manufacturing a touch sensor according to a preferred embodiment of the present invention is directed to a method of manufacturing the touch sensor 100 according to the preferred embodiment of the present invention, and the same components are denoted by the same reference numerals.

Referring to FIGS. 3 and 4, in the forming of the shielding film (S10), a shielding film 120 is formed on an edge of one surface of a transparent substrate 110. Here, the shielding film 120 may be formed in a square band type having a square hole formed in the central portion thereof.

Here, the shielding film 120 may be formed by printing an ink having low brightness, such as, black ink, on one surface of the transparent substrate 110.

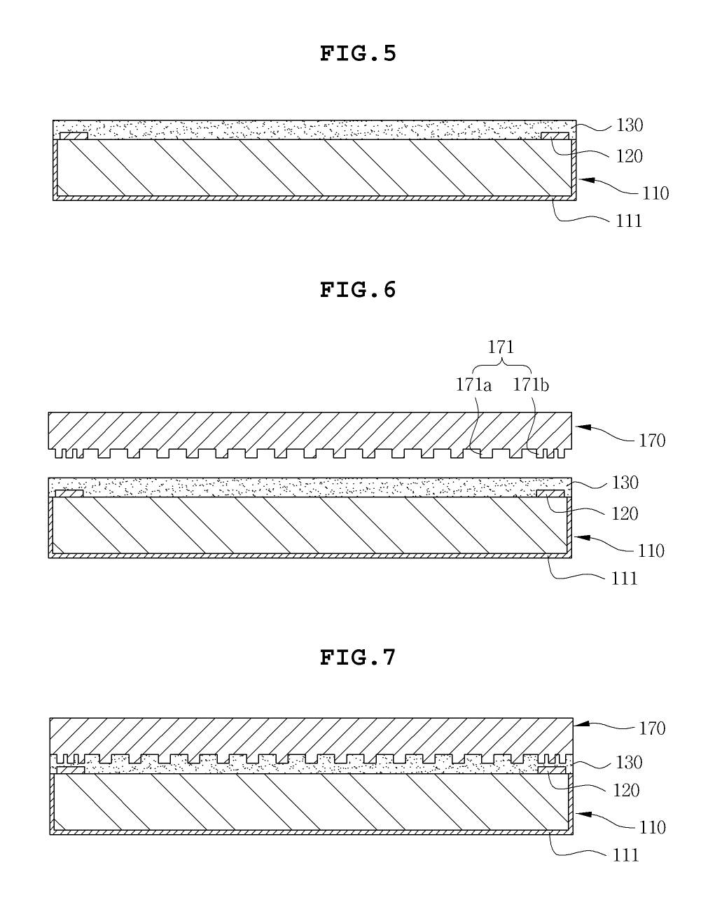

Referring to FIGS. 3 and 5, in the forming of the resin layer (S20), a first resin layer 130 is formed on the transparent substrate 110 and one surface of the shielding film 120. Here, the first resin layer 130 is made of an imprint resin, and the imprint resin is made of for example a thermoplastic resin. However, a material for the first resin layer 130 is not limited thereto.

Referring to FIGS. 3 and 6 to 8, in the forming of the electrode grooves (S30), one surface of the resin layer 130 formed of an imprint resin is imprinted to form electrode grooves 131.

Here, when one surface of the resin layer 130 is pressed by using a stamp 170 having a protrusion 171 protruded from a lower surface thereof, the electrode grooves 131 are formed in one surface of the first resin layer 130 that is pressed by the protrusion 171. Here, the protrusion 171 is used to form a pattern, and the pattern may be formed in, for example, a mesh pattern type.

In addition, the protrusion 171 may include pattern protrusions 171a and wiring protrusions 171b. Here, when the electrode grooves 131 are formed through the stamp 170, the pattern protrusions 171a form pattern grooves 131a among the electrode grooves 131, in which first electrode patterns 141 are formed of a metal layer, and the wiring protrusions 171b form wiring grooves 131b among the electrode grooves 131, in which first electrode wirings 142 are formed of a metal layer. In addition, the pattern grooves 131a are formed in a pattern type, and the wiring grooves 131b are formed along edges of the pattern grooves 131a. Here, when the pattern protrusions 171a and the wiring protrusions 171b of the stamp 170 press the first resin layer 130, the pattern grooves 131a and the wiring grooves 131b of the electrode grooves 131 are formed on the same plane.

Referring to FIG. 3 and FIGS. 9 to 11, in the forming of the electrode (S40), a first electrode 140 is formed in the electrode grooves 131. Here, the forming of the electrode (S40) may include forming a resist; forming a metal layer; and removing the resist.

Referring to FIG. 9, in the forming of the resist, a resist 180 is formed on one surface of the first resin layer 130. Here, the resist 180 may be formed of an insulation material.

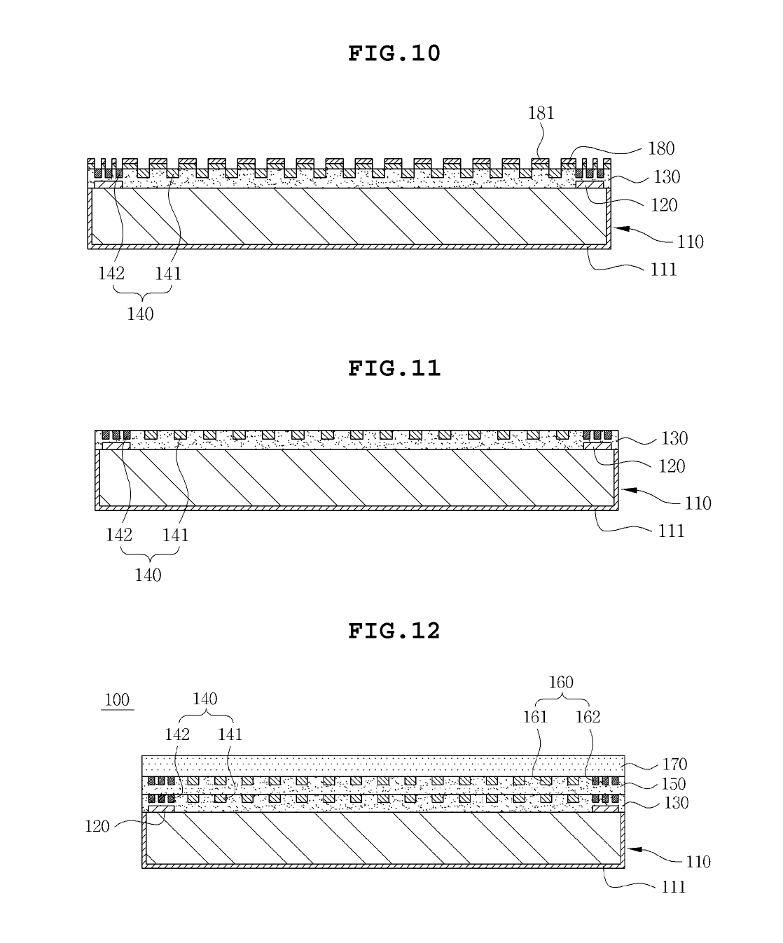

Referring to FIG. 10, in the forming of the metal layer, a metal layer is formed on one surface of the resin layer 130 on which the resist 180 is formed. Here, the metal layer is formed on the resist 180 formed on a first portion of one surface of the first resin layer 130 and is also formed in the electrode grooves formed in a second portion of one surface of the first resin layer 130.

Referring to FIG. 11, in the removing of the resist, the resist 180 formed on the first portion of one surface of the first resin layer 130 is removed after the forming of the metal layer. Therefore, the metal layer formed in the electrode grooves 131 form patterns, and resultantly, the first electrode 140 is formed in the electrode grooves 131.

Meanwhile, referring to FIG. 12, in the method of manufacturing the touch sensor according to a preferred embodiment of the present invention, the electrodes 140 and 160 may be formed in plural layers. Here, the forming procedure of the electrode as shown in FIGS. 5 to 11 is repeated one more, and thus, a second electrode 160 may be formed to be upwardly spaced apart from the first electrode 140 at a predetermined distance.

That is, in order to form the second electrode 160, a second resin layer 150 is formed by laminating an imprint resin on one surface of the first resin layer 130 in which the first electrode 140 is buried, and electrode grooves 151 are formed in one surface of the second resin layer 150 by using the stamp 170. In addition, the metal layer is formed in the electrode grooves 151 to thereby form the second electrode 160. Here, the second electrode 160 may be formed such that the second electrode 160 is buried in one surface of the second resin layer 150. Here, a procedure including forming a resist 180 on one surface of the second resin layer 150, forming a metal layer, and removing the resist 180 is the same as the procedure of forming the first electrode 140, and thus, descriptions thereof will be omitted. In addition, the first electrode 140 and the second electrode 160 may cross each other, and for example, the first electrode 140 may be formed in a horizontal direction and the second electrode 160 may be formed in a vertical direction. However, the present invention is not limited thereto.

In addition, the method of manufacturing a touch sensor according to a preferred embodiment of the present invention is not limited to forming the electrodes 140 and 160 in plural layers. However, for example, the electrode 140 may be formed in a single layer, as shown in FIG. 11.

Meanwhile, the method of manufacturing a touch sensor according to a preferred embodiment of the present invention, may further include, after forming the second electrode 160 to be buried in the second resin layer 150, forming a protecting layer 190 on one surface of the second resin layer 150 on which the second electrode 160 is formed. Here, the protecting layer 190 may be formed of, for example, acryl, but the present invention is not limited thereto. Here, the protecting layer 190 is formed of a moisture resistant type prevention layer, to thereby protect the second electrode 160 from moisture, impact, or other external environments.

Meanwhile, the method of manufacturing a touch sensor according to a preferred embodiment of the present invention may further include chemically reinforcing an outer surface of the transparent substrate 110 before the forming of the shielding film.

Here, a chemical reinforcing layer 111 may be formed by forming a chemical reinforcing agent on the other surface of the transparent substrate 110 except one surface thereof on which the electrode is formed. Here, the other surface of the transparent substrate 110 except one surface thereof may be a lateral surface and a lower surface of the transparent substrate 110, as shown in FIG. 4, but the position of the other surface of the transparent substrate 110 according to a preferred embodiment of the present invention is not limited thereto. The other surface of the transparent substrate 110 may be, of course, a lateral surface and an upper surface of the transparent substrate 110.

In addition, the chemical reinforcing agent may contain salt, such as, potassium nitrate (KNO₃), potassium chloride (KCl), or the like, and ethanol based oil that easily dissolves the salt and has excellent adsorbability to a glass surface.

In addition, the chemical reinforcing agent may be printed by a silkscreen or roller coating method.

Therefore, the chemical reinforcing agent may be printed on the other surface of the transparent substrate 110, to thereby form the chemical reinforcing layer 111, which is a protecting layer for the transparent substrate 110.

Here, the chemical reinforcing layer 111 may be more easily formed by application heat at 400˜500° C. for 4-6 hours.

The chemical reinforcing layer 111 formed as above is thermally, chemically, and physically stable, to thereby form a substrate protecting layer protecting the transparent substrate 110.

Hence, in the touch sensor 100 manufactured by the method of manufacturing a touch sensor according to a preferred embodiment of the present invention, the transparent substrate 110 is protected by the chemical reinforcing layer 111, and thus, reinforcing treatment does not need to be separately performed.

As set forth above, according to the embodiments of the present invention, the electrode is formed such that the electrode is buried in the transparent substrate, and thus, the step height between the shielding film and the electrode can be reduced.

In addition, according to the embodiments of the present invention, the electrodes are formed on the same plane, so that the electrode patterns and the electrode wires can be simultaneously formed, and thus, the manufacturing time and the manufacturing cost can be reduced.

Although the preferred embodiments of the present invention have been disclosed for illustrative purposes, they are for specifically explaining the present invention and thus a touch sensor and a method of manufacturing the same according to the present invention is not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. A touch sensor, comprising:
a transparent substrate;
a shielding film formed on one surface of the transparent substrate;
a resin layer formed above the transparent substrate and one surface of the shielding film; and
an electrode buried in one surface of the resin layer.

2. The touch sensor as set forth in claim 1, wherein the transparent substrate is formed of glass or a film.

3. The touch sensor as set forth in claim 1, wherein the shielding film is formed along an edge of one surface of the transparent substrate.

4. The touch sensor as set forth in claim 1, wherein the resin layer is formed of an imprint resin.

5. The touch sensor as set forth in claim 1, wherein the electrode includes:
electrode patterns sensing a touch; and
electrode wires electrically connected to edges of the electrode patterns, the electrode wires being shielded by the shielding film when viewed in a direction of the other surface of the transparent substrate.

6. The touch sensor as set forth in claim 4, wherein the electrode patterns are formed of a metal mesh.

7. The touch sensor as set forth in claim 4, wherein the electrode patterns and the electrode wires are formed on the same plane.

8. The touch sensor as set forth in claim 1, further comprising a protecting layer formed on one surface of the resin layer having the electrode buried therein.

9. A method of manufacturing a touch sensor, the method comprising:
forming a shielding film on one surface of a transparent substrate;
forming a resin layer above the transparent substrate and one surface of the shielding film; and
burying and forming an electrode in one surface of the resin layer.

10. The method as set forth in claim 9, wherein in the forming of the shielding film, the shielding film is formed along an edge of one surface of the transparent substrate.

11. The method as set forth in claim 9, wherein the transparent substrate is formed of glass or a film.

12. The method as set forth in claim 9, further comprising, after the forming of the electrode, forming a protecting layer on one surface of the resin layer having the electrode buried therein.

13. The method as set forth in claim 9, wherein the electrode is formed in a metal mesh pattern.

14. The method as set forth in claim 9, wherein the forming of the electrode further includes forming electrode grooves in one surface of the resin layer, the electrode grooves formed with the electrode.

15. The method as set forth in claim 14, wherein the resin layer is formed of an imprint resin.

16. The method as set forth in claim 15, wherein in the forming of the electrode grooves, the electrode grooves are formed by imprinting the resin layer.

17. The method as set forth in claim 14, wherein the electrode includes:
electrode patterns sensing a touch; and
electrode wires electrically connected to the electrode patterns,
wherein the electrode wires are shielded by the shielding film when viewed in a direction of the other surface of the transparent substrate.

18. The method as set forth in claim 17, wherein in the forming of the electrode grooves, the electrode grooves are formed such that the electrode patterns and the electrode wires are formed on the same plane.

19. The method as set forth in claim 14, wherein in the forming of the electrode, the electrode is formed in the electrode groove by plating or deposition.

20. The method as set forth in claim 14, wherein the forming of the electrode further includes:
forming a resist on one surface of the resist layer except for the electrode grooves;
forming a metal layer on one surface of the resin layer; and
removing the resist to form the electrode buried in the electrode groove.
